(19) United States
(12) Patent Application Publication
(10) Pub. No.: US 2008/0023716 A1
(43) Pub. Date: Jan. 31, 2008

(54) Semiconductor combined device, light emitting diode head, and image forming apparatus

(75) Inventors: Tomohiko Sagimori, Tokyo (JP); Mitsuhiko Ogihara, Tokyo (JP); Hiroyuki Fujiwara, Tokyo (JP); Masataka Muto, Tokyo (JP)

Correspondence Address: TAKEUCHI & KUBOTERA, LLP, SUITE 202, 200 DAINGERFIELD ROAD, ALEXANDRIA, VA, 22314, US

(73) Assignee: Oki Data Corporation

(21) Appl. No.: 11/826,903

(22) Filed: Jul. 19, 2007

(30) Foreign Application Priority Data
Jul. 25, 2006 (JP) 2006-202118

(51) Int. Cl. H01L 27/15; H01L 33/00

(52) U.S. Cl. 257/98; 257/79; 257/E27.12

(57) ABSTRACT

A semiconductor combined device includes a substrate and a light emitting element disposed on the substrate. The light emitting element includes a mesa slope inclined relative to the substrate by a first angle; a light emitting portion extending in parallel to the substrate; an interlayer insulation layer covering the mesa slope and having a surface at the mesa slope inclined relative to the substrate by a second angle smaller than the first angle; an electrode connected to the light emitting portion; and a protection layer covering the light emitting portion.

### BACKGROUND OF THE INVENTION AND RELATED ART STATEMENT

The present invention relates to a semiconductor combined device used for a light emitting diode (LED) array and the likes; a light emitting diode (LED) head including the semiconductor combined device; and an image forming apparatus including the light emitting diode (LED) head.

Patent Reference has disclosed a conventional semiconductor combined device. In the conventional semiconductor combined device, a light emitting element is disposed in a semiconductor thin layer formed on a semiconductor substrate. A drive integrated circuit for driving the light emitting element is disposed on a substrate different and separated from the semiconductor substrate. Then, the semiconductor thin layer is bonded on the substrate. Accordingly, the light emitting element and the drive circuit are disposed on the same substrate.

With the configuration described above, it is possible to integrate the light emitting element and the drive circuit, thereby eliminating a connection pad having a large size. Further, it is possible to reduce a density of connecting wires connecting the light emitting element and the drive circuit, thereby reducing a size of the semiconductor combined device.

In the conventional semiconductor combined device, an interlayer insulation layer formed of silicon nitride (SiN) is provided for covering the light emitting element with a plasma chemical vapor deposition (CVD) method and the like. FIG. 33 is a schematic sectional view showing a light emitting element of the conventional semiconductor combined device.

In the conventional semiconductor combined device shown in FIG. 33, an LED is disposed in a semiconductor thin layer bonded on a substrate through an inter-molecular force. In particular, an LED light emitting portion 121 is covered with an SiN layer 175. An opening portion 120d is formed in an upper surface of the LED light emitting portion 121. A conductive side electrode 130 is formed in the opening portion 120d.

### Patent Reference: Japanese Patent Publication No. 2002-111050

As described above, in the conventional semiconductor combined device, the semiconductor thin layer is bonded on the substrate through an inter-molecular force, thereby making it possible to make the semiconductor thin layer thin. Accordingly, the thin semiconductor layer is susceptible to an influence of an interlayer insulation layer such as the SiN layer 175 having a large layer stress.

Due to the large layer stress of the SiN layer 175, a characteristic of the LED light emitting portion 121 formed in the semiconductor thin layer tends to easily change with time. For example, a light amount of the LED light emitting portion 121 tends to easily change in continuous use.

An LED array to be disposed on a printer head is formed of a plurality of the LED light emitting portions 121. Accordingly, when a light amount of the LED light emitting portion 121 changes with time, a light amount of the LED array changes significantly (time change of light amount variance). Therefore, it is necessary to reduce the change in the light amount of the LED light emitting portion 121 formed in the semiconductor thin layer.

In view of the problems described above, an object of the present invention is to provide a semiconductor combined device with improved reliability, in which there is a minimized change in a characteristic of a light emitting element formed in a semiconductor thin layer bonded on a substrate through an inter-molecular force.

Further objects and advantages of the invention will be apparent from the following description of the invention.

### SUMMARY OF THE INVENTION

In order to attain the objects described above, according to the present invention, a semiconductor combined device includes a substrate and a light emitting element disposed on the substrate. The light emitting element includes a mesa slope inclined relative to the substrate by a first angle; a light emitting portion extending in parallel to the substrate; an interlayer insulation layer covering the mesa slope and having a surface at the mesa slope inclined relative to the substrate by a second angle smaller than the first angle; an electrode connected to the light emitting portion; and a protection layer covering the light emitting portion.

In the present invention, the light emitting element includes the light emitting portion; the interlayer insulation layer having the surface inclined relative to the substrate by the second angle smaller than the first angle; an electrode connected to the light emitting portion; the electrode connected to the light emitting portion; and the protection layer covering the light emitting portion.

When an LED light emitting element with an island shape is disposed in a semiconductor thin layer, an organic insulation layer formed of a phenolic resin covers the LED light emitting element except an upper surface thereof. The organic insulation layer has a section having a thickness decreasing toward the upper surface of the LED light emitting element. Accordingly, it is possible to reduce a stress applied to the semiconductor thin layer, thereby minimizing a change in a light amount of the LED light emitting element with time. Further, even when an SiN layer is provided at an uppermost layer, it is possible to minimize a change in a light amount of the LED light emitting element with time, thereby improving reliability of the LED light emitting element and an LED array.

### BRIEF DESCRIPTION OF THE DRAWINGS

FIG. 1 is a schematic plan view showing a semiconductor combined device according to a first embodiment of the present invention;

FIG. 2 is a schematic sectional view of the semiconductor combined device taken along a line 2-2 in FIG. 1 according to the first embodiment of the present invention;

FIG. 3 is a schematic sectional view of the semiconductor combined device taken along a line 3-3 in FIG. 1 according to the first embodiment of the present invention;

FIG. 4 is a schematic sectional view of the semiconductor combined device taken along a line 4-4 in FIG. 1 according to the first embodiment of the present invention;

FIG. 5 is a schematic reference view No. 1 of the semiconductor combined device according to the first embodiment of the present invention;

FIG. 6 is a schematic reference view No. 2 of the semiconductor combined device according to the first embodiment of the present invention;

FIG. 7 is a schematic reference view No. 3 of the semiconductor combined device according to the first embodiment of the present invention;

FIG. 8 is a schematic reference view No. 4 of the semiconductor combined device according to the first embodiment of the present invention;

FIG. 9 is a schematic sectional view No. 1 showing a validation experiment of the semiconductor combined device according to the first embodiment of the present invention;

FIG. 10 is a schematic sectional view No. 2 showing the validation experiment of the semiconductor combined device according to the first embodiment of the present invention;

FIG. 11 is a schematic sectional view showing a modified example of the semiconductor combined device according to the first embodiment of the present invention;

FIG. 12 is a schematic sectional view showing a semiconductor combined device according to a second embodiment of the present invention;

FIG. 13 is a schematic sectional view showing a modified example of the semiconductor combined device according to the second embodiment of the present invention;

FIG. 14 is a schematic sectional view showing a semiconductor combined device according to a third embodiment of the present invention;

FIG. 15 is a schematic reference view of the semiconductor combined device according to the third embodiment of the present invention;

FIG. 16 is a schematic sectional view showing a modified example of the semiconductor combined device according to the third embodiment of the present invention;

FIG. 17 is a schematic plan view showing a semiconductor combined device according to a fourth embodiment of the present invention;

FIG. 18 is a schematic sectional view showing a modified example of the semiconductor combined device according to the fourth embodiment of the present invention;

FIG. 19 is a schematic plan view showing a semiconductor combined device according to a fifth embodiment of the present invention;

FIG. 20 is a schematic sectional view showing a modified example No. 1 of the semiconductor combined device according to the fifth embodiment of the present invention;

FIG. 21 is a schematic sectional view showing a modified example No. 2 of the semiconductor combined device according to the fifth embodiment of the present invention;

FIG. 22 is a schematic plan view showing a semiconductor combined device according to a sixth embodiment of the present invention;

FIG. 23 is a schematic sectional view of the semiconductor combined device taken along a line 23-23 in FIG. 22 according to the sixth embodiment of the present invention;

FIG. 24 is a schematic sectional view of the semiconductor combined device taken along a line 24-24 in FIG. 22 according to the sixth embodiment of the present invention;

FIG. 25 is a schematic sectional view of the semiconductor combined device taken along a line 25-25 in FIG. 22 according to the sixth embodiment of the present invention;

FIG. 26 is a schematic plan view showing a semiconductor combined device according to a seventh embodiment of the present invention;

FIG. 27 is a schematic plan view showing a semiconductor combined device according to an eighth embodiment of the present invention;

FIG. 28 is a schematic sectional view of the semiconductor combined device taken along a line 28-28 in FIG. 27 according to the eighth embodiment of the present invention;

FIG. 29 is a schematic sectional view of the semiconductor combined device taken along a line 29-29 in FIG. 27 according to the eighth embodiment of the present invention;

FIG. 30 is a schematic view showing a printer head using a light emitting diode (LED) according to a ninth embodiment of the present invention;

FIG. 31 is a schematic plan view of the printer head according to the ninth embodiment of the present invention;

FIG. 32 is a schematic sectional view showing an image forming apparatus according to the present invention; and

FIG. 33 is a schematic sectional view showing a light emitting element of a conventional semiconductor combined device.

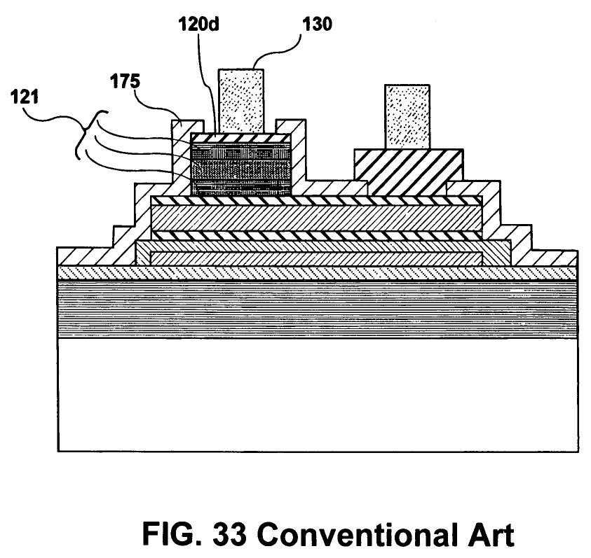

### DETAILED DESCRIPTION OF PREFERRED EMBODIMENTS

Hereunder, embodiments of the present invention will be explained with reference to the accompanying drawings.

### First Embodiment

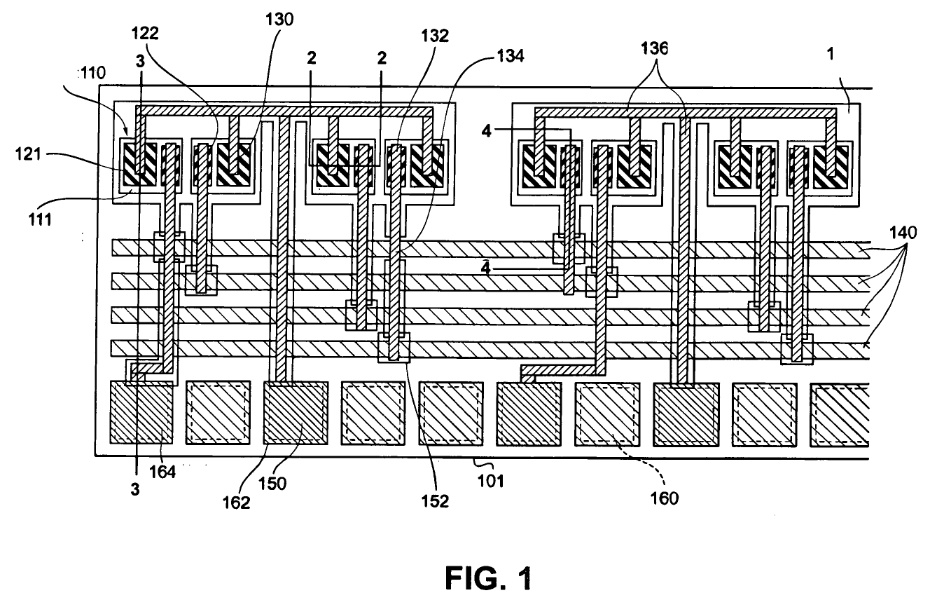

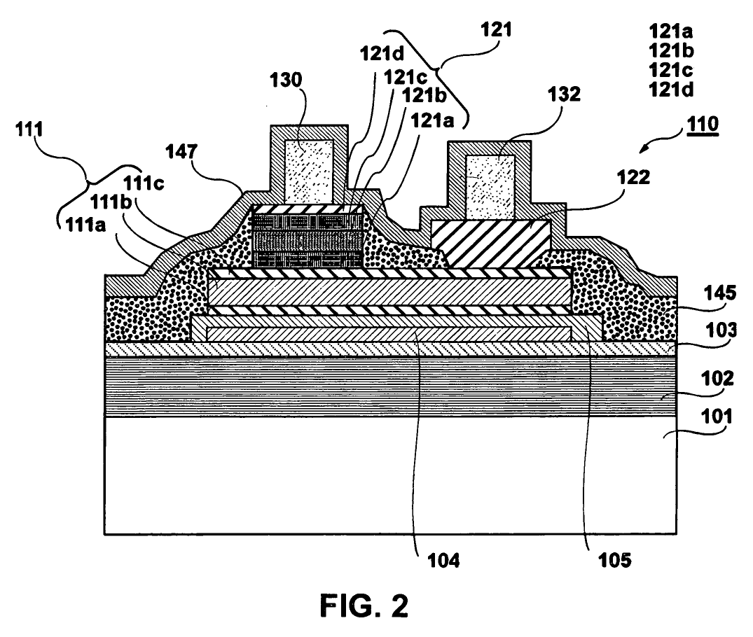

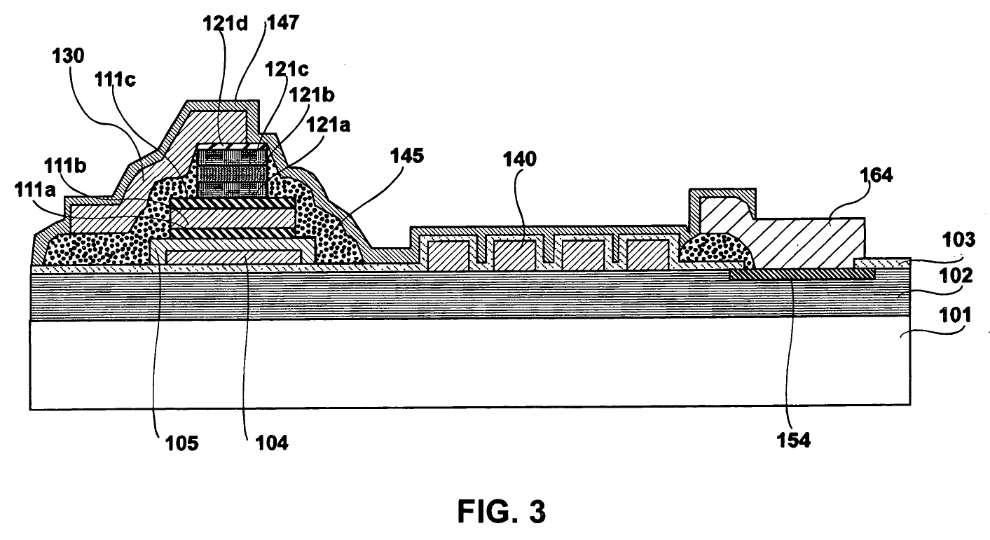

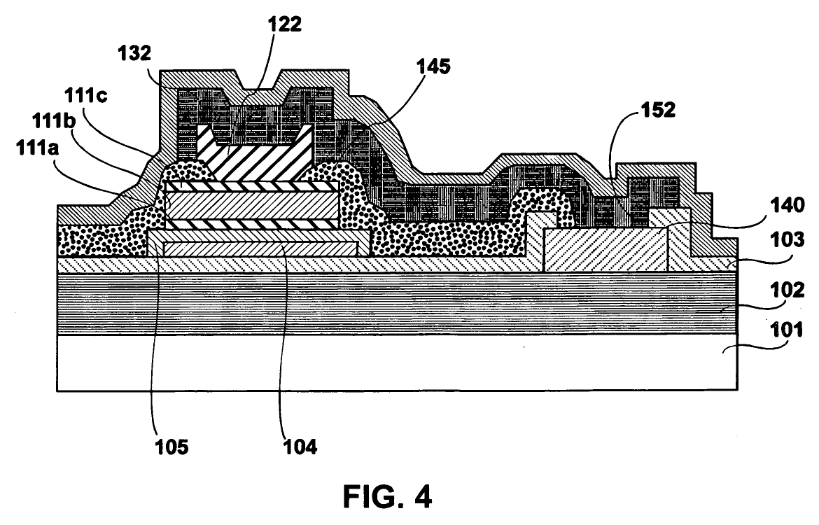

A first embodiment of the present invention will be explained. FIG. 1 is a schematic plan view showing a semiconductor combined device according to the first embodiment of the present invention. FIG. 2 is a schematic sectional view of the semiconductor combined device taken along a line 2-2 in FIG. 1 according to the first embodiment of the present invention. FIG. 3 is a schematic sectional view of the semiconductor combined device taken along a line 3-3 in FIG. 1 according to the first embodiment of the present invention. FIG. 4 is a schematic sectional view of the semiconductor combined device taken along a line 4-4 in FIG. 1 according to the first embodiment of the present invention.

As shown in FIG. 1, in the semiconductor combined device, light emitting areas are arranged in a row, and the arrangement and the number of rows are adjustable. Further, in the semiconductor combined device, four of light emitting elements are arranged in one block to be driven through a matrix drive, and the number of light emitting elements in one block and the number of blocks disposed in one chip are adjustable. The light emitting elements may be driven through a static drive instead of the matrix drive.

A configuration of the semiconductor combined device shown in FIG. 1 will be explained. For the sake of explanation, in FIG. 1, parts of the configuration shown in FIGS. 2 to 4 such as a base insulation layer of a semiconductor thin layer, a reflection layer below the semiconductor thin layer, a multilayer wiring layer of a drive integrated circuit and the likes are omitted.

As shown in FIG. 1, the semiconductor combined device is provided with an integrated circuit substrate 101 formed of a silicon substrate. Light emitting diode (LED) light emitting portions 121 are formed in semiconductor thin layers 110. LED lower layer areas 111 are provided for exposing first conductive side contact layers in the semiconductor thin layers 110. First conductive side electrodes 122 are formed on the first conductive side contact layers on the LED lower layer areas 111.

In the embodiment, second conducive side electrodes 130 are provided for contacting with surfaces of the light emitting portions 121. Further, the semiconductor combined device is provided with first conductive side wiring patterns 132 and 134, and second conductive side wiring patterns 136. Common wiring patterns 140 are provided for connecting the first conductive side wiring patterns 132 and 134 in each block at a same level.

In the embodiment, the semiconductor combined device is provided with organic interlayer insulation layers 145. LED control output pads 150 are provided for connecting the second conductive side wiring patterns 136 and integrated circuits. Common wiring connecting opening portions 152 are provided for connecting the first conductive side wiring patterns 134 and the common wiring patterns 140.

In the embodiment, signal input connecting pads 160 are provided for inputting and outputting power source and a control signal for controlling the drive integrated circuits from outside. Wiring connecting areas 162 are provided for covering the LED control output pads 150. The wiring connecting areas 162 may be formed of a material, for example, same as that of the first conductive side wiring patterns 134, and may completely cover the LED control output pads 150 and the signal input connecting pads 160. Connecting areas 164 are provided for connecting a first conductive side and the integrated circuits or an external circuit.

As shown in FIG. 2, each of the LED light emitting portions 121 is formed in one of the semiconductor thin layers 110 divided individually. A plurality of the LED light emitting portions 121 may be formed in the semiconductor thin layers 110 connected continuously.

In the embodiment, each of the LED light emitting portions 121 is formed of an island area formed through mesa etching, so that the first conductive side contact layer on a lower layer area in the semiconductor thin layer 110 is exposed. The island area is formed of, for example, a first conductive type clad layer 121a, a first conductive type active layer 121b, a second conductive type clad layer 121c, and a second conductive type contact layer 121d. Further, the island area constitutes a semiconductor epitaxial layer.

More specifically, the first conductive type clad layer 121a may be formed of an AlₓGa₁₋ₓAs layer; the first conductive type active layer 121b may be formed of an Al_{y}Ga_{1-y}As layer; the second conductive type clad layer 121c may be formed of an Al_{z}Ga_{1-z}As layer; and the second conductive type contact layer 121d may be formed of a GaAs layer.

In the embodiment, the LED lower layer area 111 is formed of a first conductive type bonding layer 111a, a first conductive type conduction layer 111b, and a first conductive type contact layer 111c. More specifically, the first conductive type bonding layer 111a may be formed of a GaAs layer; the first conductive type conduction layer 111b may be formed of an AlₜGa₁₋ₜAs layer; and the first conductive type contact layer 111c may be formed of a GaAs layer. Values of x, z, and t are preferably larger than that of y (x, z, t>y).

As shown in FIG. 2, the semiconductor thin layer 110 is bonded on the drive integrated circuit for drive controlling the LED light emitting portion 121 formed on a silicon (Si) substrate. The semiconductor combined device is provided with the integrated circuit substrate 101 formed of the Si substrate; a multilayer wiring layer 102 of the drive integrated circuit; an insulation layer 103 on the multilayer wiring layer 102; a reflection layer 104 formed of a metal layer for reflecting light emitting from a backside of the LED light emitting portion 121; and a flattening layer 105 formed of an organic layer such as a polyimide layer for directly bonding the semiconductor thin layer 110.

In the embodiment, the reflection layer 104 is formed of a metal layer of Ti, Ti/PtAu, TiAl, Cr/Au, NiAl, Ag, an Au type alloy containing Ag, an Al type alloy, and an Ag type alloy. Further, the first conductive side electrode 122 for forming an ohmic contact with an n-type GaAs layer may be formed of, for example, AuGe/Ni/Au or AuGeNi/Au. Further, the second conducive side electrode 130 for forming an ohmic contact with an p-type GaAs layer may be formed of, for example, Ti/Pt/Au. The first conductive side wiring pattern 132 may be formed of Ti/Pt/Au.

In the embodiment, the interlayer insulation layer 145 directly contacts with side surfaces of the LED light emitting portion 121 in an island shape, and is formed of an organic material for reducing a stress applied to the LED light emitting portion 121. It is preferred that the interlayer insulation layer 145 is formed of a material having a small volume change rate upon curing and capable of curing at a low temperature, thereby minimizing the stress applied to the semiconductor thin layer 110.

More specifically, the interlayer insulation layer 145 is preferably formed of an organic layer with a phenolic resin as a main component. Further, the interlayer insulation layer 145 may be formed of an organic layer with a cresol resin as a main component; an organic layer containing a phenolic resin and a quinone-azide derivative; an organic layer containing a phenolic resin and an azide compound derivative; and an organic layer containing a phenolic resin and an indene-carboxylic acid.

As shown in FIG. 1, the organic insulation layers 145 are preferably disposed around only the wiring patterns and the connecting portions except the semiconductor thin layer areas and surrounding areas thereof, thereby minimizing an influence of a layer stress on the integrated circuit areas.

As shown in FIG. 2, the interlayer insulation layer 145 is disposed on the side surfaces of the LED light emitting portion 121 in the island shape, and has a section having a thickness of the organic insulation layer decreasing toward an upper surface of the island shape. Further, the interlayer insulation layer 145 is preferably disposed only on a slope of the LED light emitting portion 121 in the island shape.

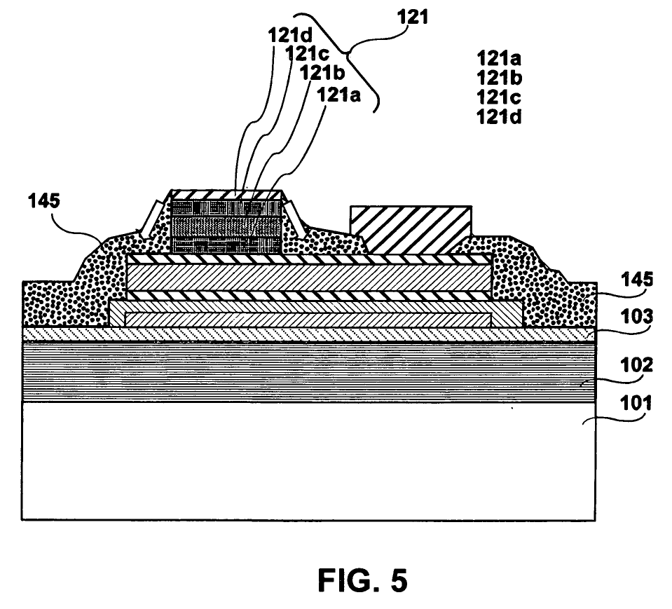

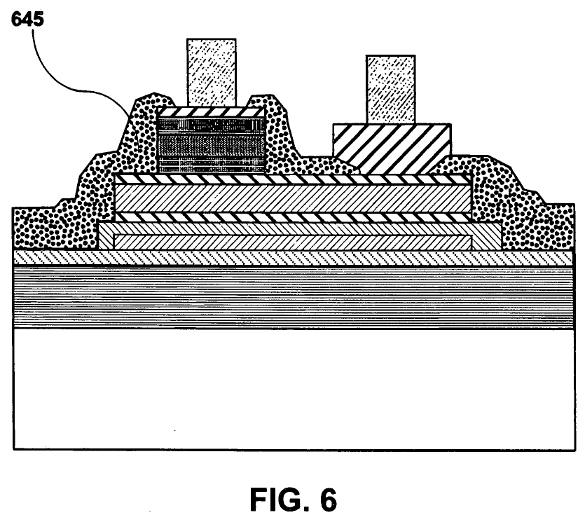

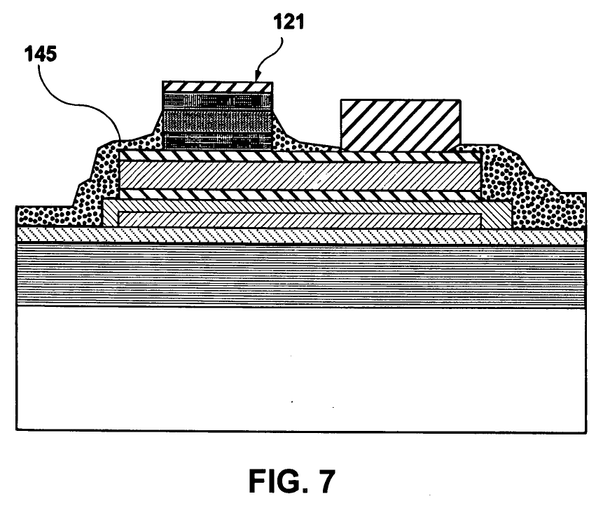

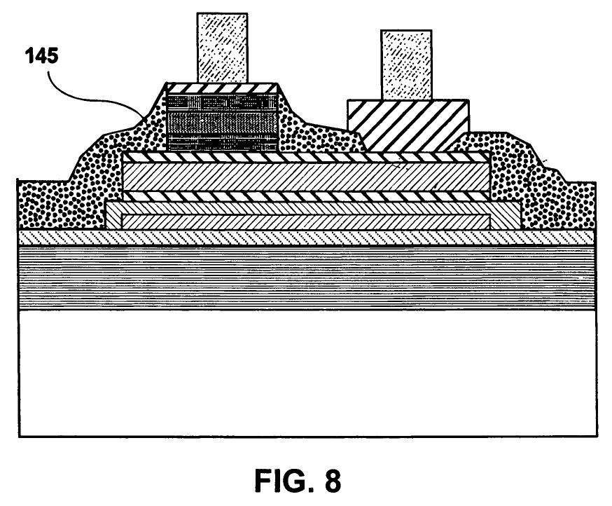

FIG. 5 is a schematic reference view No. 1 of the semiconductor combined device according to the first embodiment of the present invention. FIG. 6 is a schematic reference view No. 2 of the semiconductor combined device according to the first embodiment of the present invention. FIG. 7 is a schematic reference view No. 3 of the semiconductor combined device according to the first embodiment of the present invention. FIG. 8 is a schematic reference view No. 4 of the semiconductor combined device according to the first embodiment of the present invention When the interlayer insulation layer 145 has a thickness decreasing toward the upper surface of the island shape shown in FIG. 2, a layer stress is dispersed obliquely in an arrow direction shown in FIG. 5. Accordingly, it is possible to reduce the stress applied to the LED light emitting portion 121 in the island shape.

In an experiment, when an organic insulation layer 645 was formed over the upper surface of the LED light emitting portion 121, it was difficult to disperse the stress applied to the LED light emitting portion 121 as effective as the case described above. As a result, it was difficult to minimize a change in a light amount of the LED light emitting portion 121 with time.

In the embodiment, it is preferred that the interlayer insulation layer 145 has a thickness (at a flat surface) of larger than 0.5 μm. In another experiment, as shown in FIG. 7, when the interlayer insulation layer 145 has a thickness of less than 0.5 μm, it was difficult to completely cover the side surfaces of the LED light emitting portion 121 with the interlayer insulation layer 145, thereby exposing the upper surface of the LED light emitting portion 121, especially exposing the active layer area.

When the interlayer insulation layer 145 does not completely cover the side surfaces of the LED light emitting portion 121 as shown in FIG. 7, and a part thereof is exposed, the semiconductor layer may be etched and damaged through a developing liquid or a releasing liquid in a photolithography process. Further, the side surfaces may be contaminated, thereby causing side current leaking. In this case, when an oxygen ashing process is conducted during a manufacturing process, the side surfaces may be oxidized to cause an interfacial difference, thereby causing a current leaking or non-light-emitting re-coupling. In any cases, an initial characteristic of the LED light emitting portion 121 or a characteristic of the LED light emitting portion 121 during an operation is deteriorated.

When the interlayer insulation layer 145 has a thickness of larger than 0.5 μm, it is possible to obtain a good initial characteristic of the LED light emitting portion 121, i.e., an initial characteristic of the LED light emitting portion 121 same as that in a case when the interlayer insulation layer is formed of an SiN layer. Further, it is possible to prevent a characteristic of the LED light emitting portion 121 from fluctuating relative to an operation time occurring in a case when the interlayer insulation layer is formed of an SiN layer.

Even when the LED light emitting portion 121 is provided with only the interlayer insulation layer 145 as shown in FIG. 8, it is possible to significantly minimize a change in a light amount with time upon energizing the LED light emitting portion 121. Accordingly, it is possible to minimize a light amount change ratio less than 1%. The light amount change ratio is defined as a ratio of an initial light amount P(O) to a light amount P(t) after a period of time t, i.e., P(t)−P(O)/P(O)×100(%).

In order to further improve reliability of the LED light emitting portion 121, as shown in FIG. 3, a protection layer 147 is preferably provided, so that at least the upper surface of the LED light emitting portion 121 is covered. The protection layer 147 may be formed of an inorganic layer such as an SiN layer, or may be formed of a material same as that of the interlayer insulation layer 145.

Further, as shown in FIGS. 3 and 4, the protection layer 147 is preferably disposed to cover the first conductive side electrode 122 (FIG. 4), the second conducive side electrode 130 (FIG. 3), and the first conductive side wiring pattern 132 (FIG. 4). Through covering the contact metals and the wiring patterns on the semiconductor thin layer 110, it is possible to reduce a stress applied to the wiring patterns of the LED light emitting portion 121 during a dicing process and a mounting process, thereby preventing a defect in the semiconductor thin layer 110 and improving reliability of the contact portions.

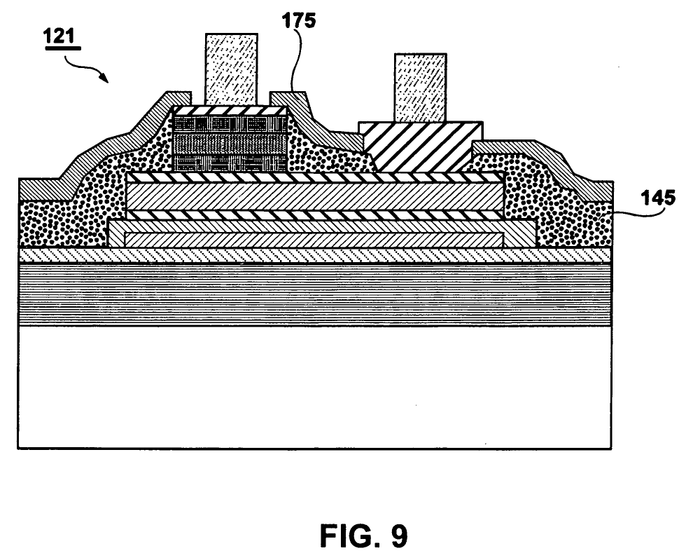

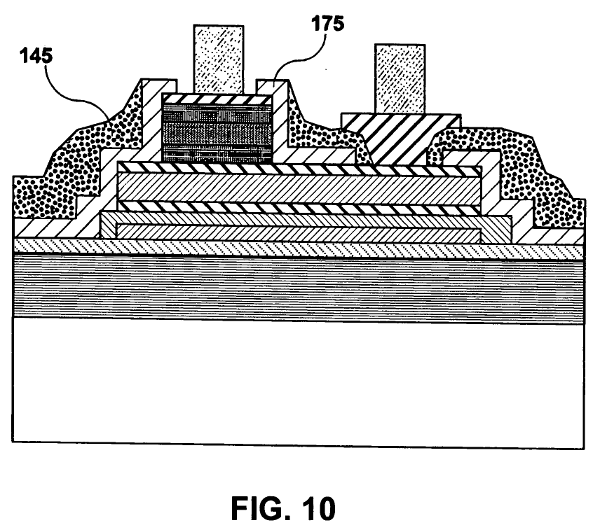

FIG. 9 is a schematic sectional view No. 1 showing a validation experiment of the semiconductor combined device according to the first embodiment of the present invention. FIG. 10 is a schematic sectional view No. 2 showing the validation experiment of the semiconductor combined device according to the first embodiment of the present invention.

In the validation experiment shown in FIG. 9, when an SiN layer 175 having an opening portion was provided on the upper surface of the LED light emitting portion 121 to cover the interlayer insulation layer 145, it was possible to reduce a change in the light amount. In the validation experiment shown in FIG. 10, when the SiN layer 175 having an opening portion was provided on the upper surface of the LED light emitting portion 121, and the interlayer insulation layer 145 was provided on the SiN layer 175, it was difficult to reduce a change in the light amount.

In the validation experiment described above, the difference may be attributed to an effect of the stress applied to the semiconductor thin layer 110. When the SiN layer 175 was formed on the interlayer insulation layer 145, the layer stress becomes smaller one order than that in the case when the SiN layer 175 having a same thickness covered the interlayer insulation layer 145.

Considering the result of the validation experiment, it is supposed that the interlayer insulation layer 145 preferably has a thickness of less than 5.0 μm, i.e., ten times of 0.5 μm. When the interlayer insulation layer 145 has a ten times larger thickness, it is supposed that the semiconductor thin layer 110 receives a stress equivalent to that in a case when only an SiN layer is formed.

In the embodiment, the LED light emitting portion 121 in the semiconductor thin layer 110 (or the semiconductor thin layer 110) is formed of a semiconductor compound material of AlGaAs type, and may be formed of other materials. For example, the LED light emitting portion 121 may be formed of GaAs, InP, GaAsP, InGaAsP, AlGaAsP, AlGaInP, GaInP, ZnO, or a nitride compound type semiconductor such as GaN, AlGaN, and InGaN.

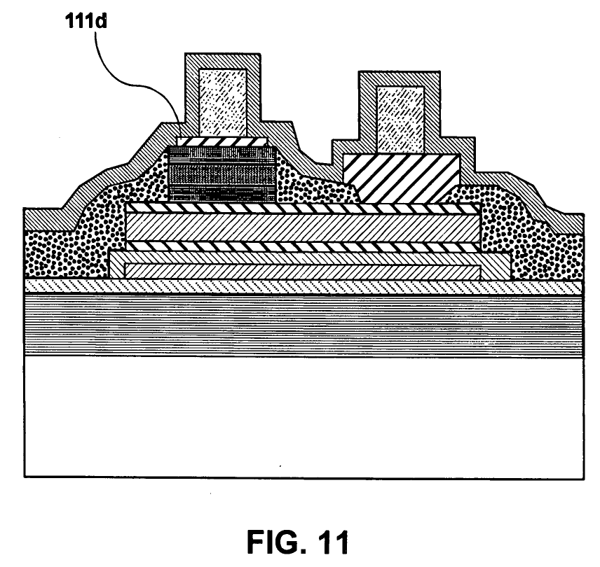

FIG. 11 is a schematic sectional view showing a modified example of the semiconductor combined device according to the first embodiment of the present invention.

As shown in FIG. 11, the uppermost layer of the LED light emitting portion 121 (GaAs contact layer 111d) does not extend to a mesa edge. Instead, the uppermost layer of the LED light emitting portion 121 is disposed a part of the upper surface within an area contacting with the electrode.

In the embodiment, the components are integrated on the Si substrate, and are not necessarily formed on the Si substrate. Further, the configuration is not limited to the one in which the drive integrated circuit and the LED light emitting element are integrated on the Si substrate. Further, other modifications are possible such as omitting the reflection layer or providing the first conductive side electrode on a backside of the semiconductor thin layer.

Further, instead of the Si substrate, an integrated circuit (formed of, for example, poly-silicon) and a light emitting element array are integrated on a glass substrate, a ceramic substrate, a metal substrate, or an organic substrate. Further, it is possible to obtain the stress reduction effect in a sensor element such as a light reception element instead of the light emitting element such as an LED.

In the embodiment, the first conductive side electrode 122 is formed of a material different from that of the first conductive side wiring pattern 132, and may be formed of a same material.

As described above, in the embodiment, the semiconductor thin layer is formed on the substrate formed of a different material. The LED light emitting portion is formed in the semiconductor thin layer in the island shape. The organic insulation layer containing a phenolic resin and the likes is formed on the LED light emitting portion, so that the section of the organic insulation layer has a thickness decreasing toward the upper surface of the LED light emitting portion. The organic insulation layer does not cover the upper surface of the LED light emitting portion.

With the configuration described above, it is possible to significantly reduce a stress applied to the semiconductor thin layer, thereby preventing a change in the light amount of the LED light emitting portion with time. Further, even when the SiN layer is provided at the uppermost surface, it is possible to prevent a change in the light amount of the LED light emitting portion with time, thereby obtaining the LED light emitting portion and the LED array with high reliability.

### Second Embodiment

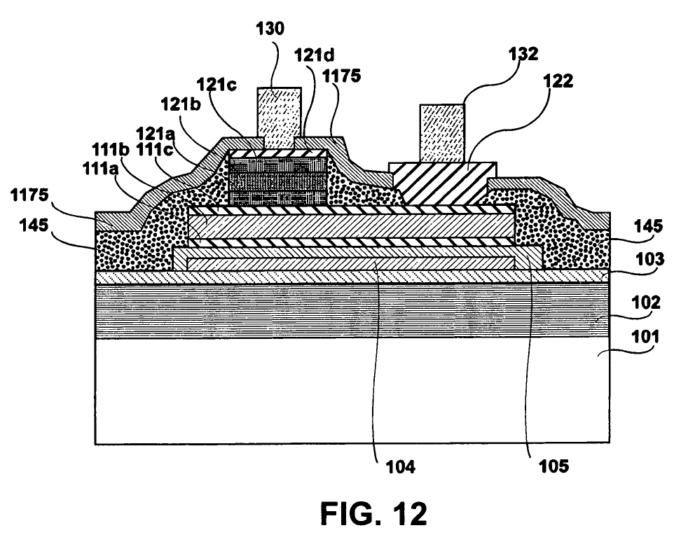

A second embodiment of the present invention will be explained next. FIG. 12 is a schematic sectional view showing a semiconductor combined device according to the second embodiment of the present invention.

As shown in FIG. 12, different from the semiconductor combined device in the first embodiment, the semiconductor combined device in the second embodiment is provided with, in addition to the interlayer insulation layer 145 (first interlayer insulation layer), an inorganic interlayer insulation layer 1175 (second interlayer insulation layer). An opening portion of the second interlayer insulation layer is completely covered, so that the GaAs contact layer 121d is not exposed. Components in the second embodiment similar to those in the first embodiment are designated with the same reference numerals.

As shown in FIG. 12, the opening portion of the inorganic interlayer insulation layer 1175 on the LED light emitting portion 121 is covered with the second conducive side electrode 130, so that the GaAs contact layer 121d is not exposed. The inorganic interlayer insulation layer 1175 may be formed of an SiN layer, an SiON layer, an SiO₂ layer, a PSG layer, a BSG layer, and the likes.

In the embodiment, the first conductive side electrode 122 is formed in the opening portions of the interlayer insulation layer 145 and the inorganic interlayer insulation layer 1175. The opening portion of the interlayer insulation layer 145 is situated inside the opening portion of the inorganic interlayer insulation layer 1175, and may be situated outside the opening portion of the inorganic interlayer insulation layer 1175.

In the embodiment, it is preferred that the opening portion of the inorganic interlayer insulation layer 1175 for the p-side electrode contact is formed before the opening portion for the n-side electrode contact is formed. After the p-side electrode contact covers the opening portion of the inorganic interlayer insulation layer 1175, it is preferred that the opening portion for the n-side electrode contact and the n-side electrode contact are formed.

In the embodiment, before the inorganic interlayer insulation layer 1175 is formed, the interlayer insulation layer 145 is formed on the side surfaces of the LED light emitting portion 121 as described in the first embodiment. Similar to the first embodiment, it is preferred that the interlayer insulation layer 145 has a section having a thickness decreasing upward. Further, it is preferred that the interlayer insulation layer 145 has a thickness substantially equal to λ/4n (λ is a wave length of light emitting from the LED light emitting portion 121, and n is a reflective index). With the thickness, it is possible to improve light emission efficiency of the LED light emitting portion 121 without decreasing light output efficiency.

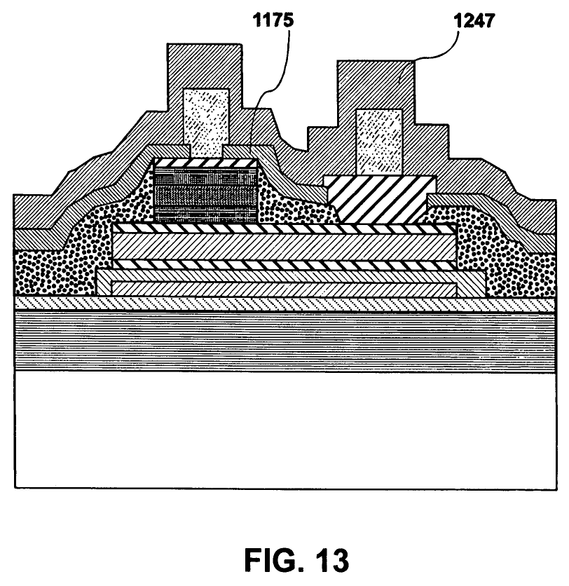

FIG. 13 is a schematic sectional view showing a modified example of the semiconductor combined device according to the second embodiment of the present invention. Similar to the first embodiment, a protection layer 1247 is provided at the uppermost layer for covering the electrodes and the wiring patterns. The protection layer 1247 may be formed of an SiN layer, an SiON layer, an SiO₂ layer, a BSG layer, and the likes.

When the protection layer 1247 is provided, thicknesses of the inorganic interlayer insulation layer 1175 and the protection layer 1247 are determined to be suitable for obtaining maximum light emission efficiency, considering λ/4n as described above.

As described above, in the embodiment, in addition to the organic insulation layer, the inorganic interlayer insulation layer having the opening portion is provided on the upper surface of the LED light emitting portion. The electrode covers the opening portion of the inorganic interlayer insulation layer, so that the contact layer is not exposed. Accordingly, in addition to the effect in the first embodiment, it is possible to prevent the contact layer from being damaged during a manufacturing process of the LED, thereby improving reliability of the LED.

### Third Embodiment

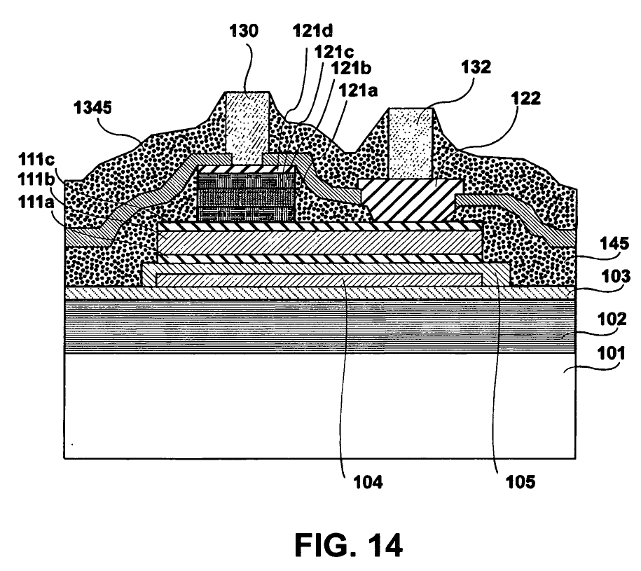

A third embodiment of the present invention will be explained next. FIG. 14 is a schematic sectional view showing a semiconductor combined device according to the third embodiment of the present invention.

As shown in FIG. 14, different from the semiconductor combined devices in the first embodiment and the second embodiment, the semiconductor combined device in the third embodiment is provided with a protection layer covering the second conducive side electrode 130 and the first conductive side wiring pattern 132 having a side surface inclined more gently than that of at least a side surface of an electrode. Components in the third embodiment similar to those in the first and second embodiments are designated with the same reference numerals.

As shown in FIG. 14, the semiconductor combined device is provided with a protection layer 1345 for covering uppermost layers of elements formed in the semiconductor thin layer 110. The protection layer 1345 covers side surfaces of the second conducive side electrode 130 and the first conductive side wiring pattern 132, so that the protection layer 1345 has an inclination larger than those of the side surfaces of the second conducive side electrode 130 and the first conductive side wiring pattern 132.

In the embodiment, the protection layer 1345 is formed of an organic layer with a phenolic resin as a main component, and may be formed of an organic layer with a cresol resin as a main component; an organic layer containing a phenolic resin and a quinone-azide derivative; an organic layer containing a phenolic resin and an azide compound derivative; and an organic layer containing a phenolic resin and an indene-carboxylic acid.

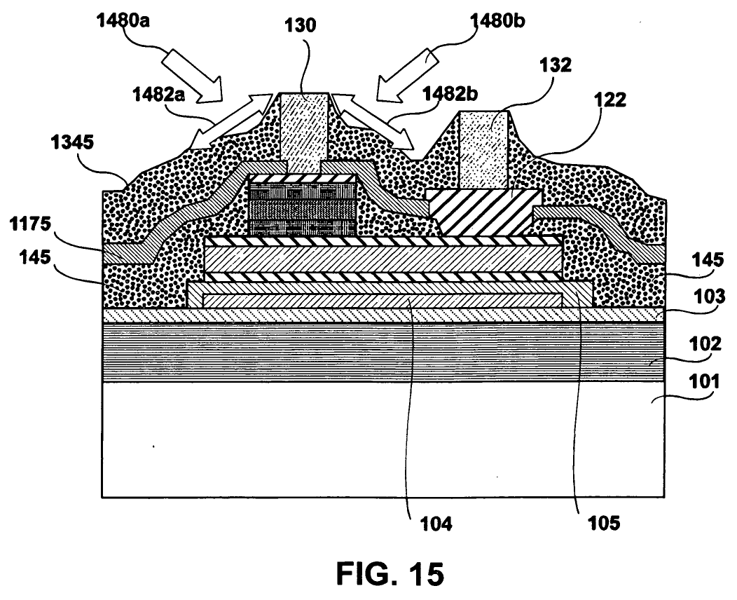

FIG. 15 is a schematic reference view of the semiconductor combined device according to the third embodiment of the present invention. When a wafer is diced into individual chips, a relatively strong water pressure is applied to the wafer through rotation of a dicing blade. In FIG. 15, arrows 1480a and 1480b represent a water pressure applied to the side surfaces of the second conducive side electrode 130 and the first conductive side wiring pattern 132.

In the embodiment, considering resistances of the electrodes and the wiring patterns, the second conducive side electrode 130 and the first conductive side wiring pattern 132 preferably have a thickness between 500 nm and 1.0 μm, so that the second conducive side electrode 130 and the first conductive side wiring pattern 132 become relatively thick portions (large heights). When the water pressure 1480a and 1480b is applied to the second conducive side electrode 130 and the first conductive side wiring pattern 132 with such heights, a relatively large stress is applied to the second conducive side electrode 130 and the first conductive side wiring pattern 132, thereby applying a large stress to the semiconductor thin layer 110 or the semiconductor layer contacting the second conducive side electrode 130 and the first conductive side wiring pattern 132.

As shown in FIG. 15, the second conducive side electrode 130 and the first conductive side wiring pattern 132 have vertical side surfaces. In an actual case, many of such electrodes have a slant surface with inclination. When an electrode has a slant side surface, it is preferred that a layer is provided for covering the side surface, so that the layer has inclination larger than that of the side surface of the electrode, thereby dispersing a stress applied to the electrode.

That is, as shown in FIG. 15, the stresses 1480a and 1480b applied to the second conducive side electrode 130 and the first conductive side wiring pattern 132 are dispersed and converted into stresses 1482a and 1482b. With the protection layer 1345 formed of the material described above, it is possible to provide the side surfaces of the second conducive side electrode 130 and the first conductive side wiring pattern 132 with larger inclination.

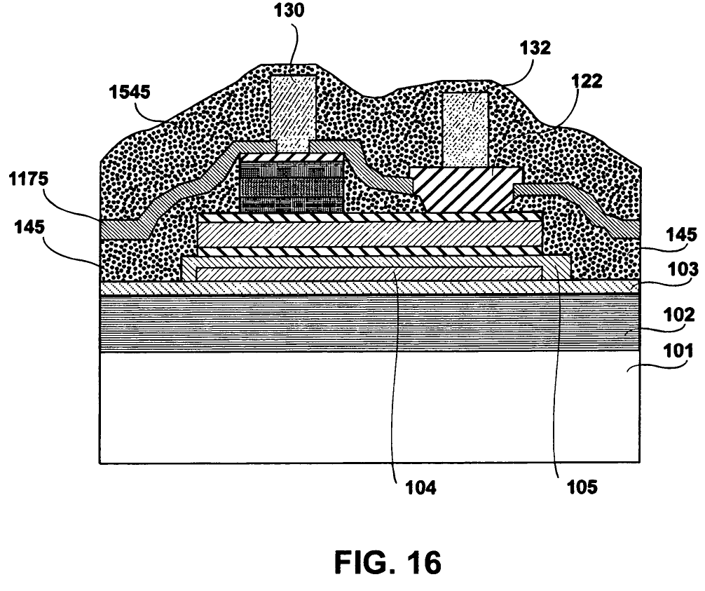

FIG. 16 is a schematic sectional view showing a modified example of the semiconductor combined device according to the third embodiment of the present invention. In the modified example, an organic insulation layer 1545 is provided on the second conducive side electrode 130 and the first conductive side wiring pattern 132, such that the organic insulation layer 1545 has inclination larger than that of the side surfaces of the second conducive side electrode 130 and the first conductive side wiring pattern 132. The organic insulation layer 1545 may cover the upper surfaces of the second conducive side electrode 130 and the first conductive side wiring pattern 132.

As described above, in the embodiment, the protection layer 1345 or the organic insulation layer 1545 are formed on the second conducive side electrode 130 and the first conductive side wiring pattern 132, such that the protection layer 1345 or the organic insulation layer 1545 has inclination larger than that of the side surfaces of the second conducive side electrode 130 and the first conductive side wiring pattern 132. Accordingly, it is possible to disperse a stress applied to the second conducive side electrode 130 and the first conductive side wiring pattern 132 and the semiconductor thin layer 110 contacting with the second conducive side electrode 130 and the first conductive side wiring pattern 132.

### Fourth Embodiment

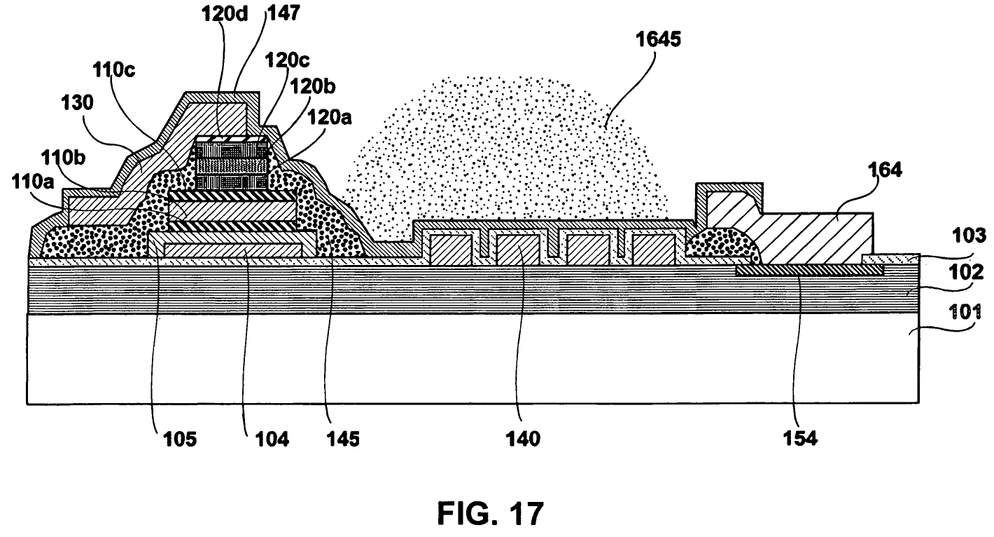

A fourth embodiment of the present invention will be explained next. FIG. 17 is a schematic plan view showing a semiconductor combined device according to the fourth embodiment of the present invention.

As shown in FIG. 17, different from the semiconductor combined devices in the first to third embodiments, the semiconductor combined device in the fourth embodiment is provided with a light blocking layer 1645 on the protection layer 147 for preventing light emitting from the LED light emitting portion 121 from reflecting on a wire disposed for connecting to an external circuit. The light blocking layer 1645 may be formed of an organic layer having a thickness of about 6.0 μm.

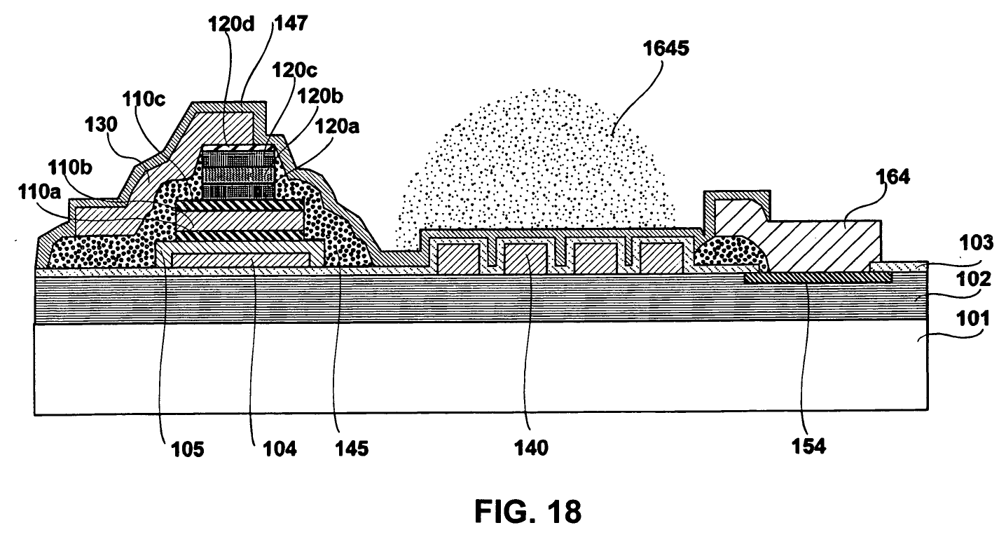

FIG. 18 is a schematic sectional view showing a modified example of the semiconductor combined device according to the fourth embodiment of the present invention. In the semiconductor combined device shown in FIG. 17, the light blocking layer 1645 overlaps with the interlayer insulation layer 145. On the other hand, as shown in FIG. 18, the light blocking layer 1645 may be arranged without an area overlapping with the interlayer insulation layer 145.

As described above, in the embodiment, in addition to the organic insulation layer covering the mesa slope of the semiconductor thin layer 110 and the protection layer 147 covering the uppermost layers, the light blocking layer 1645 is disposed in a connecting area between the LED light emitting portion 121 and the external circuit. Accordingly, in addition to the effects of the first to third embodiments, it is possible to prevent light emitting from the LED light emitting portion 121 from reflecting on a connecting wire.

### Fifth Embodiment

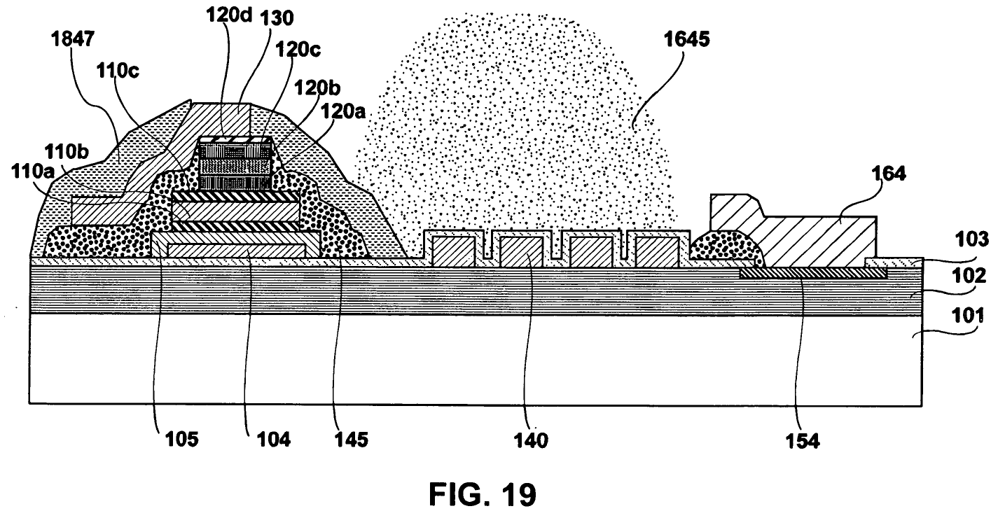

A fifth embodiment of the present invention will be explained next. FIG. 19 is a schematic plan view showing a semiconductor combined device according to the fifth embodiment of the present invention.

As shown in FIG. 19, different from the semiconductor combined devices in the first to fourth embodiments, the semiconductor combined device in the fifth embodiment is provided with an organic protection layer 1847 mainly in an area covering the semiconductor thin layer 110 for reducing the inclination of the side surfaces of the second conducive side electrode 130. Further, the semiconductor combined device in the fifth embodiment is provided with the light blocking layer 1645.

As shown in FIG. 19, the organic protection layer 1847 is formed to reduce the inclination of the side surfaces of the second conducive side electrode 130. The organic protection layer 1847 is formed in an area covering the semiconductor thin layer 110, and is preferably limited therein. The organic protection layer 1847 may be formed of a material described in the third embodiment.

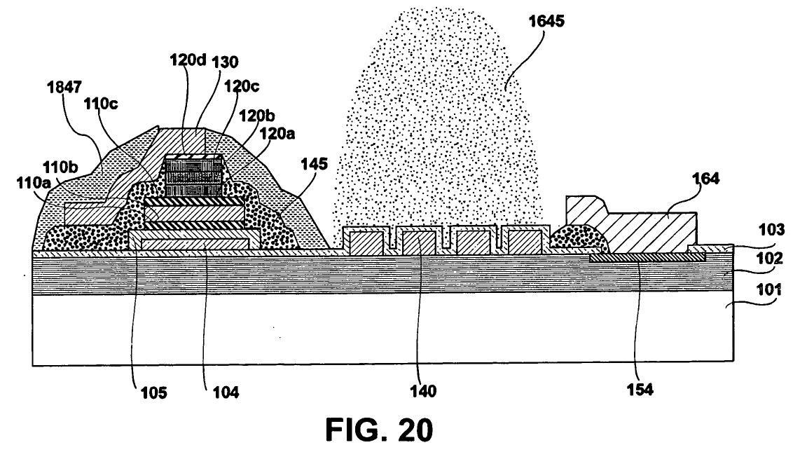

FIG. 20 is a schematic sectional view showing a modified example No. 1 of the semiconductor combined device according to the fifth embodiment of the present invention. In the semiconductor combined device shown in FIG. 19, the light blocking layer 1645 overlaps with the interlayer insulation layer 145. On the other hand, as shown in FIG. 18, the light blocking layer 1645 may be formed to have a height sufficient enough to block reflection, and may be arranged away from the LED light emitting portion 121 without an area overlapping with the interlayer insulation layer 145.

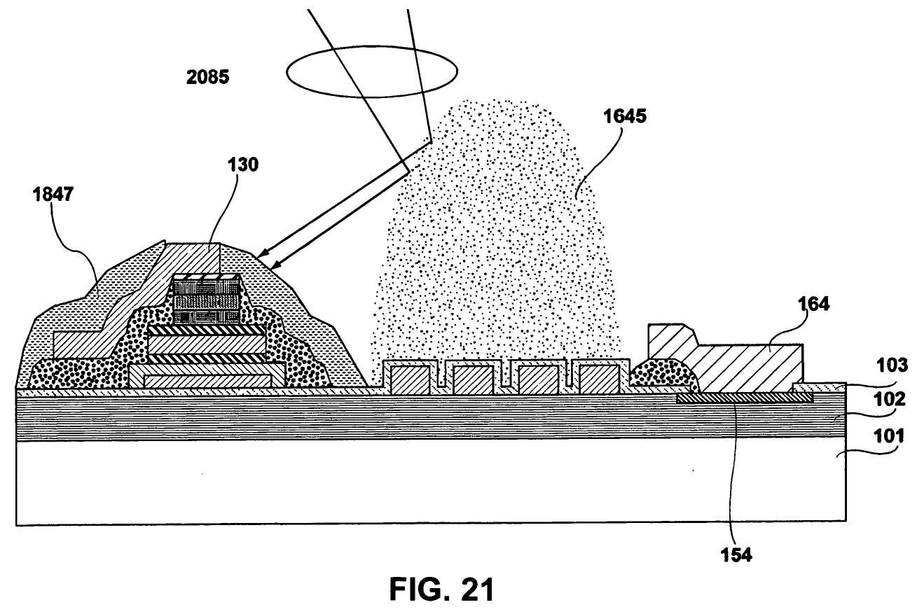

FIG. 21 is a schematic sectional view showing a modified example No. 2 of the semiconductor combined device according to the fifth embodiment of the present invention. As shown in FIG. 21, when a strong water stream deflects on the light blocking layer 1645 situated adjacent to the LED light emitting portion 121, a water pressure 2085 may be applied to the semiconductor thin layer 110 and the side surfaces of the second conducive side electrode 130. The organic protection layer 1847 is formed to reduce the inclination of the side surfaces of the second conducive side electrode 130. Accordingly, it is possible to disperse the water pressure 2085, thereby reducing the stress applied to the second conducive side electrode 130 and the semiconductor thin layer 110.

As described above, in the embodiment, the light blocking layer 1645 is disposed. Further, the organic protection layer 1847 covers only the slope of the LED light emitting portion 121 and reduces the inclination of the side surfaces of the LED light emitting portion 121. Accordingly, it is possible to disperse a water pressure applied to the second conducive side electrode 130 and the semiconductor thin layer 110, and prevent a defect due to the water pressure, thereby further improving reliability of the semiconductor combined device.

### Sixth Embodiment

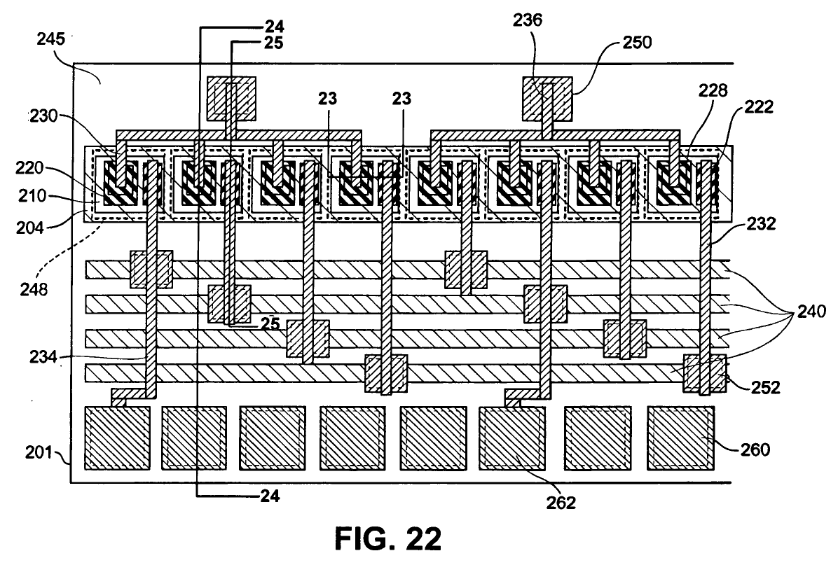

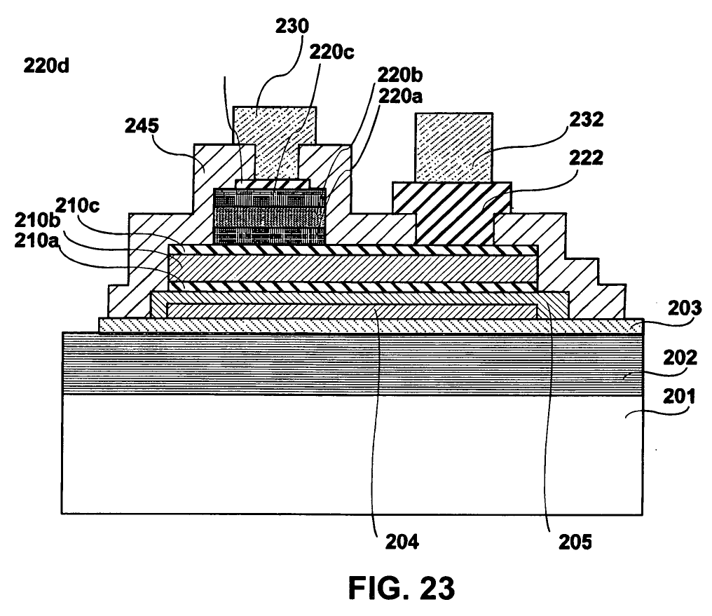

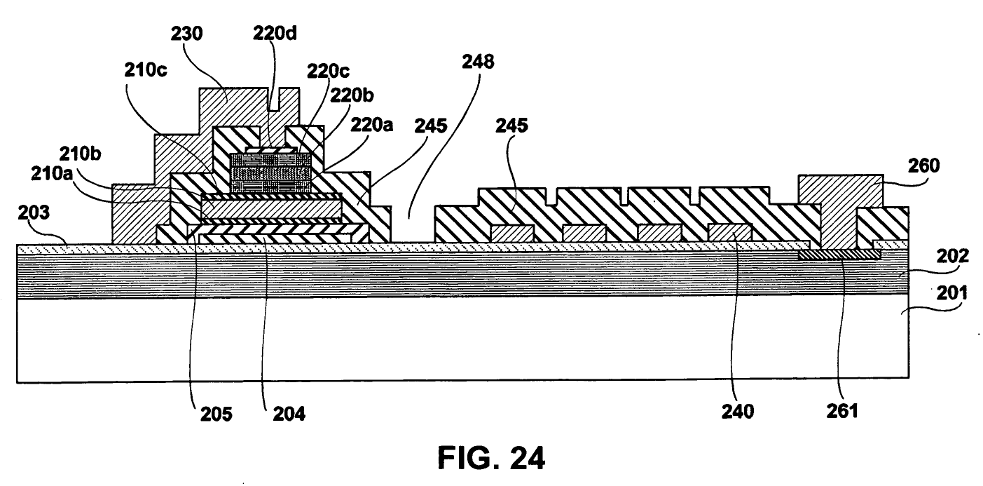

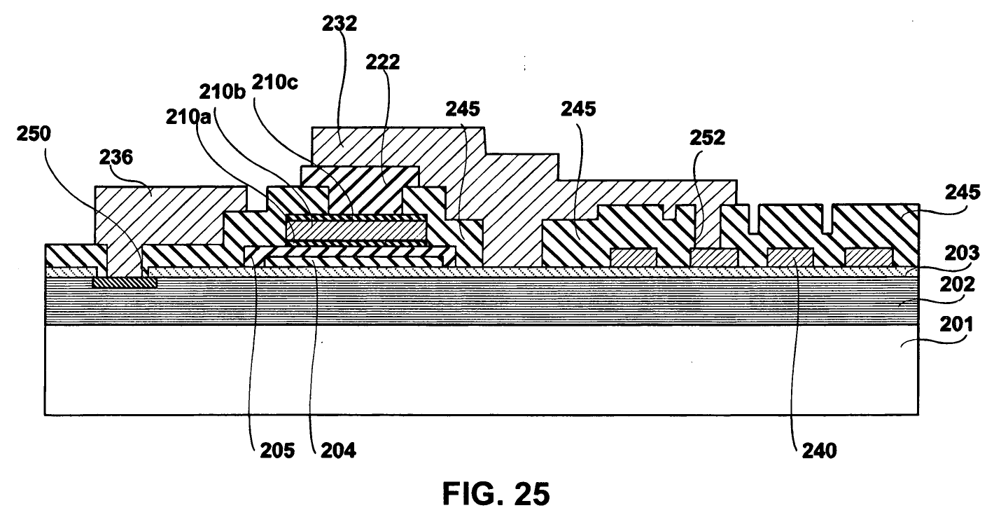

A sixth embodiment of the present invention will be explained next. FIG. 22 is a schematic plan view showing a semiconductor combined device according to the sixth embodiment of the present invention. FIG. 23 is a schematic sectional view of the semiconductor combined device taken along a line 23-23 in FIG. 22 according to the sixth embodiment of the present invention. FIG. 24 is a schematic sectional view of the semiconductor combined device taken along a line 24-24 in FIG. 22 according to the sixth embodiment of the present invention. FIG. 25 is a schematic sectional view of the semiconductor combined device taken along a line 25-25 in FIG. 22 according to the sixth embodiment of the present invention.

As shown in FIG. 22, in the semiconductor combined device, the light emitting areas are arranged in a row, and the arrangement and the number of rows are adjustable. Further, in the semiconductor combined device, four of the light emitting elements are arranged in one block to be driven through a matrix drive, and the number of light emitting elements in one block and the number of blocks disposed in one chip are adjustable. The light emitting elements may be driven through a static drive instead of the matrix drive.

As shown in FIG. 22, the semiconductor combined device is provided with an integrated circuit substrate 201 formed of a silicon substrate. Light emitting diode (LED) light emitting portions 220 are formed in semiconductor thin layers 210. First conductive side electrodes 222 are formed in the semiconductor thin layers 210. Second conducive side electrodes 230 are provided for contacting with surfaces of the light emitting portions 220. Further, the semiconductor combined device is provided with first conductive side wiring patterns 232 and 234 and second conductive side wiring patterns 236. Common wiring patterns 240 are provided for connecting the first conductive side wiring patterns 232 in each block at a same level.

In the embodiment, connecting pads 250 are provided for connecting the second conductive side wiring patterns 236 and integrated circuits. Common wiring connecting portions 252 are provided for connecting the first conductive side wiring patterns 232 and the common wiring patterns 240. Further, the semiconductor combined device is provided with input/output connecting pads 260 and connecting areas 162.

In the embodiment, an interlayer insulation layer 245 is formed of an insulation material such as, for example, SiN, SiON, SiO₂, Al₂O₃, and AIN. The interlayer insulation layer 245 may be formed of an organic material. The interlayer insulation layer 245 has interlayer insulation layer separation areas 248 near the semiconductor thin layers 210. The interlayer insulation layer separation areas 248 are arranged in areas of the semiconductor thin layers 210 adjacent to an arrangement direction of the LED light emitting portions 220.

FIG. 23 is a schematic sectional view of the semiconductor combined device taken along a line 23-23 in FIG. 22 according to the sixth embodiment of the present invention. In the embodiment, the LED light emitting portion 220 in the semiconductor thin layer 210 formed of a semiconductor compound material of AlGaAs type, and may be formed of other materials. For example, the LED light emitting portion 220 may be formed of GaAs, InP, GaAsP, InGaAsP, AlGaAsP, AlGaInP, GaInP, ZnO, or a nitride compound semiconductor such as GaN, AlGaN, and InGaN.

As shown in FIG. 23, the semiconductor combined device is provided with an integrated circuit substrate 201 formed of an Si substrate; a multilayer wiring layer 202 or an integrated circuit area formed on the integrated circuit substrate 201; and an insulation layer 203 formed on an uppermost layer of the integrated circuit area (integrated circuit wafer). Further, the semiconductor combined device is provided with a reflection layer 204 formed of a metal for reflecting upward light emitting from the LED light emitting portion 220 toward a backside of the wafer; and a flattening layer 105 for directly bonding the semiconductor thin layer 210 to the integrated circuit substrate 201.

In the embodiment, the reflection layer 204 is formed of a metal such as Ti, Ti/PtAu, TiAl, Cr/Au, NiAl, Ag, an Au type alloy containing Ag, an Al type alloy, and an Ag type alloy.

In the embodiment, an epitaxial semiconductor layer 210a is formed of n-GaAs; an epitaxial semiconductor layer 210b is formed of n-AlₜGa₁₋ₜAs; and an epitaxial semiconductor layer 210c is formed of n-GaAs.

In the embodiment, the LED light emitting portion 220 is formed of a first conductive type clad layer 220a, a first conductive type active layer 220b, a second conductive type clad layer 220c, a second conductive type contact layer 220d. More specifically, the first conductive type clad layer 220a is formed of n-Al_{z}Ga_{1-z}As; the first conductive type active layer 220b is formed of n-Al_{y}Ga_{1-y}As layer; the second conductive type clad layer 220c is formed of p-AlₓGa₁₋ₓAs layer; and the second conductive type contact layer 220d is formed of p-GaAs.

In the embodiment, the first conductive side electrode 222 is formed of a material for forming an ohmic contact with a GaAs layer, for example, AuGe/Ni/Au. The second conductive side electrode 230 is formed of a material for forming an ohmic contact with a GaAs layer, for example, Ti/Pt/Au. The first conductive side wiring pattern 232 may be formed of Ti/Pt/Au.

FIG. 24 is a schematic sectional view of the semiconductor combined device taken along a line 24-24 in FIG. 22 according to the sixth embodiment of the present invention. As shown in FIG. 24, the interlayer insulation layer 245 is separated with the interlayer insulation layer separation area 248 adjacent to the semiconductor thin layers 210.

FIG. 25 is a schematic sectional view of the semiconductor combined device taken along a line 25-25 in FIG. 22 according to the sixth embodiment of the present invention. As shown in FIG. 25, the connecting pad 250 is provided for connecting the second conductive side wiring pattern 236, and is connected to the integrated circuit.

In the embodiment, the components are integrated on the Si substrate, and are not necessarily formed on the Si substrate. Further, the configuration is not limited to the one in which the drive integrated circuit and the LED light emitting element are integrated on the Si substrate. Instead of the Si substrate, an integrated circuit (formed of, for example, poly-silicon) and a light emitting element array are integrated on a glass substrate, a ceramic substrate, a metal substrate, or an organic substrate. Further, it is possible to obtain the stress reduction effect in a sensor element such as a light reception element instead of the light emitting element such as an LED.

In the embodiment, the light emitting portions 220 are formed of a material different from that of the first conductive side wiring patterns 232, and may be formed of a same material.

As described above, in the embodiment, the interlayer insulation layer 245 is separated from the semiconductor thin layers 210 with the interlayer insulation layer separation area 248 (FIGS. 22 and 24). Accordingly, it is possible to reduce a stress applied to the semiconductor thin layers 210 and prevent a defect such as a crack due to the stress applied to the semiconductor thin layers 210, thereby improving reliability of the semiconductor combined device.

### Seventh Embodiment

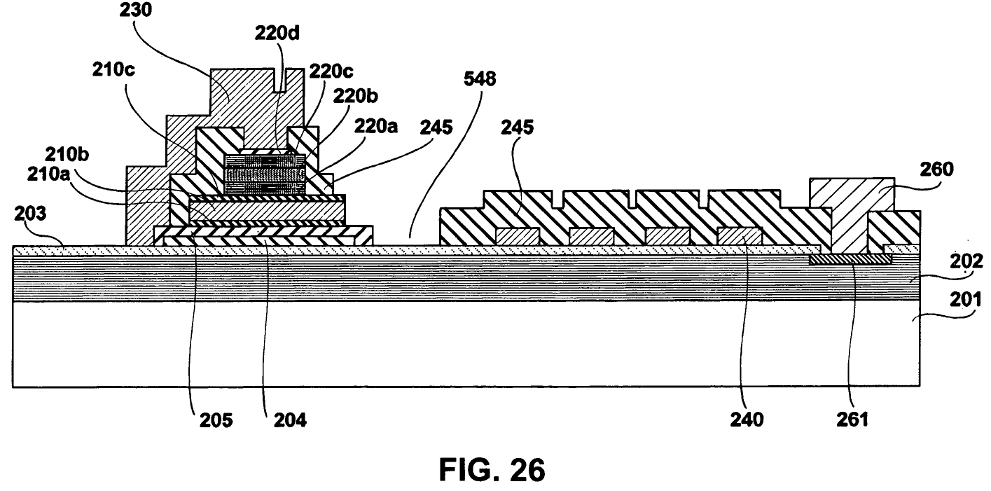

A seventh embodiment of the present invention will be explained next. FIG. 26 is a schematic sectional view showing a semiconductor combined device according to the seventh embodiment of the present invention.

As shown in FIG. 26, different from the semiconductor combined device in the sixth embodiment, the semiconductor combined device in the seventh embodiment is provided with an interlayer insulation layer separation area 548 extending to the semiconductor thin layer 210, as opposed to the interlayer insulation layer separation area 248 (FIGS. 22 and 24).

As shown in FIG. 26, the interlayer insulation layer 245 is separated at the semiconductor thin layer 210 with the interlayer insulation layer separation area 548. In an area where the second conducive side electrode 230 is disposed, when a side surface of the semiconductor thin layers 210 is exposed, it is necessary to cover the side surface of the semiconductor thin layer 210 for preventing short circuit between the first conductive side and the second conductive side. On the other side, it is not necessary to cover the side surface of the semiconductor thin layers 210 on a side of the common wiring patterns 240. Accordingly, it is possible to minimize an area of the semiconductor thin layer 210 covered with the interlayer insulation layer 245.

As described above, in the embodiment, the interlayer insulation layer separation area 548 extends to the semiconductor thin layer 210, so that the interlayer insulation layer 245 is separated on the semiconductor thin layer 210. Accordingly, it is possible to reduce an influence of a stress of the interlayer insulation layer 245 on the semiconductor thin layer 210, thereby improving reliability of the semiconductor combined device.

### Eighth Embodiment

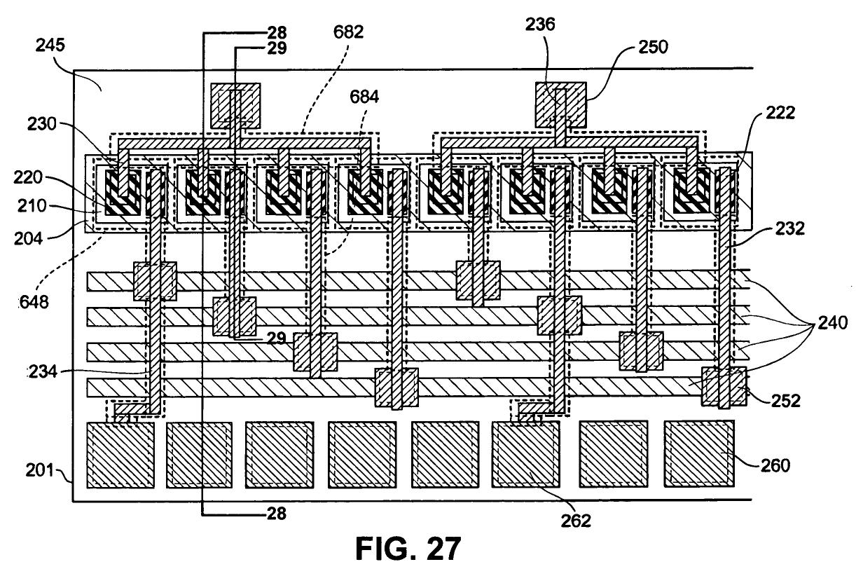

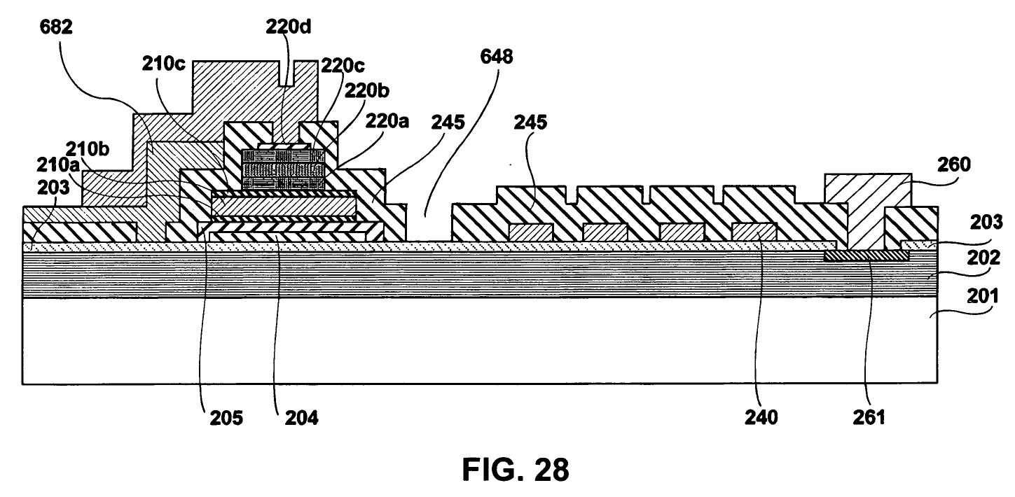

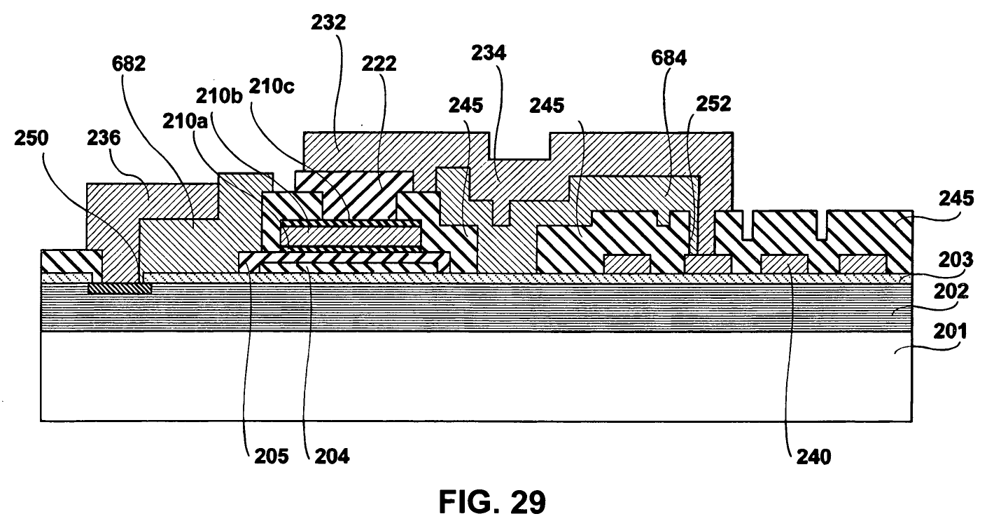

An eighth embodiment of the present invention will be explained next. FIG. 27 is a schematic plan view showing a semiconductor combined device according to the eighth embodiment of the present invention. FIG. 28 is a schematic sectional view of the semiconductor combined device taken along a line 28-28 in FIG. 27 according to the eighth embodiment of the present invention. FIG. 29 is a schematic sectional view of the semiconductor combined device taken along a line 29-29 in FIG. 27 according to the eighth embodiment of the present invention.

As shown in FIG. 27, different from the semiconductor combined devices in the sixth and seventh embodiments, the semiconductor combined device in the eighth embodiment is provided with interlayer insulation layer separation areas 648 adjacent to or on the semiconductor thin layer 210 for separating the interlayer insulation layer 245. Further, the semiconductor combined device in the eighth embodiment is provided with second interlayer insulation layers 682 and 684 below areas where wiring patterns 234 and 236 are disposed.

As shown in FIG. 28, the semiconductor combined device is provided with the interlayer insulation layer 245, the interlayer insulation layer separation areas 648, and the second interlayer insulation layer 682. The second interlayer insulation layer 682 is formed of, for example, an organic insulation layer or a coated layer. Further, the second interlayer insulation layer 682 is disposed below the area where the wiring patterns and the electrodes are disposed, and covers an edge of the semiconductor thin layer 210 and an edge of the wiring connecting opening portion.

As shown in FIG. 29, the semiconductor combined device is provided with the second interlayer insulation layer 684 disposed below the first conductive side wiring pattern 234. The second interlayer insulation layer 684 covers an edge of the wiring connecting opening portion 252. The interlayer insulation layer 245 may cover the semiconductor thin layer 210 or a surrounding area thereof, and the second interlayer insulation layer 684 covers a remaining area.

As described above, in the embodiment, in addition to the interlayer insulation layer 245, the second interlayer insulation layers 682 and 684 are provided for covering the area below the wiring patterns, the edge of the semiconductor thin layer 210, and the wiring connecting opening portion. Accordingly, it is possible to reduce an influence of a stress of the interlayer insulation layer 245 on the semiconductor thin layer 210, thereby improving reliability of the semiconductor combined device.

### Ninth Embodiment

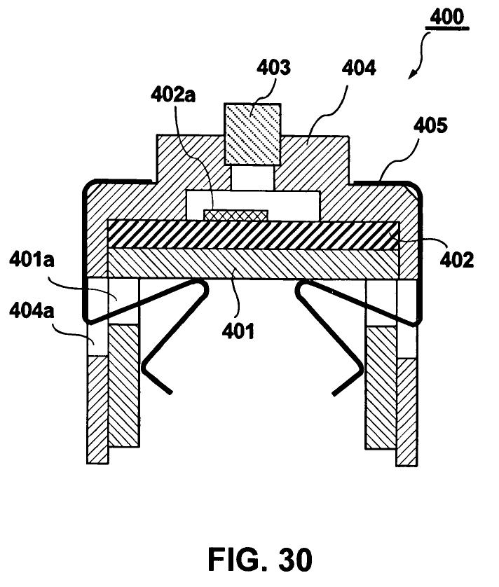

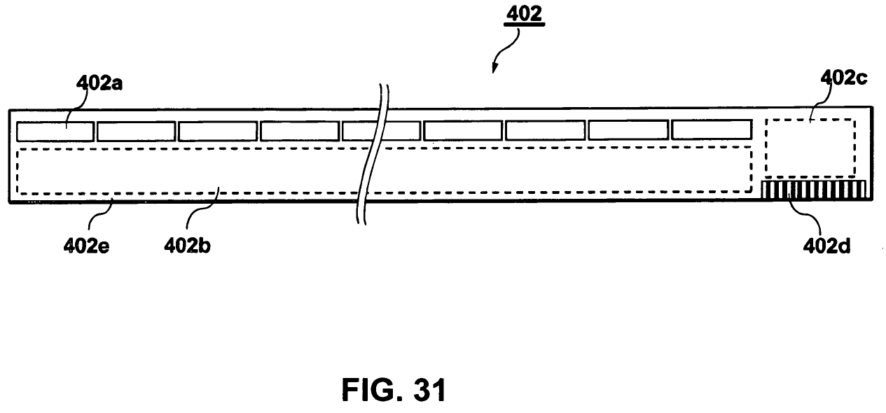

In a ninth embodiment, the semiconductor combined devices in the first to eight embodiments are applied to an image forming apparatus. FIG. 30 is a schematic view showing a printer head using the light emitting diode (LED) according to the ninth embodiment of the present invention. FIG. 31 is a schematic plan view of the printer head according to the ninth embodiment of the present invention.

As shown in FIG. 30, an LED head 402 is mounted on a base member 401. The LED head 402 is provided with one of the semiconductor combined devices in the first to eighth embodiments.

As shown in FIG. 31, a plurality of the semiconductor combined devices, in which the light emitting portions and the drive portions are combined, is arranged as light emitting units 402a on a mounting substrate 402e along a longitudinal direction thereof. Wiring patterns for arranging electrical components are disposed on the mounting substrate 402e. Further, the mounting substrate 402e includes electrical component mounting areas 402b and 402c, and a connector 402d for receiving power and a control signal from outside.

As shown in FIG. 30, a rod lens array 403 is disposed on the light emitting portion of the light emitting unit 402a as an optical element for conversing light emitting from the light emitting portion. A plurality of the rod lens arrays 403 formed of optical lenses with a column shape is arranged along the light emitting portions of the light emitting units 402a arranged linearly. A lens holder 404 as an optical element holder holds the rod lens array 403 at a specific position.

As shown in FIG. 30, the lens holder 404 covers the base member 401 and the LED head 402. A damper 405 is arranged through opening portions 401a and 404a formed in the base member 401 and the lens holder 404, so that the clamper 405 integrally holds the base member 401, the LED head 402, and the lens holder 404. Accordingly, light emitting from the LED head 402 irradiates a specific outer member through the rod lens array 403. An LED printer head 400 with the configuration described above is used as an exposure device of a photoelectric printer or a photoelectric copier.

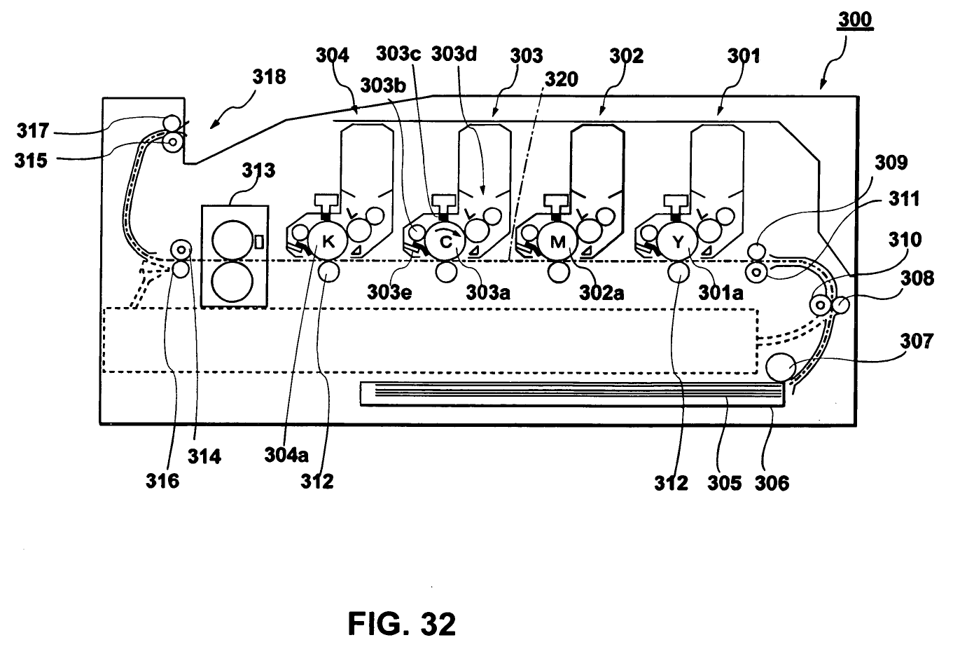

FIG. 32 is a schematic sectional view showing an image forming apparatus 300 according to the present invention. As shown in FIG. 32, four process units 301 to 304 are arranged in this order from an upstream side along a transport path 320 of a recoding medium 305 for forming images in yellow, magenta, cyan, and black, respectively. The process units 301 to 304 have an identical internal configuration, and the process unit 303 will be explained as an example.

In the process unit 303, a photosensitive drum 303a as an image supporting member is disposed to be rotatable in an arrow direction. Around the photosensitive drum 303a from an upstream side with respect to rotation of the photosensitive drum 303a, there are arranged a charging device 303b for supplying electricity and charging a surface of the photosensitive drum 303a; and an exposure device 303c for selectively irradiating light on the surface of the photosensitive drum 303a thus charged to form a static latent image thereon.

Further, there are arranged a developing device 303d for attaching toner of cyan to the surface of the photosensitive drum 303a with the latent image formed thereon; and a cleaning device 303e for removing toner remaining on the surface of the photosensitive drum 303a. Note that the photosensitive drum 303a, the charging device 303b, the exposure device 303c, the developing device 303d, and the cleaning device 303e are driven with a drive source and a gear (not shown).

In the embodiment, the image forming apparatus 300 is provided with a sheet cassette 306 at a lower portion thereof for storing the recording medium 305 in a stacked state, and a hopping roller 307 above the sheet cassette 307 for separating and transporting the recording medium 305 one by one. At a downstream side of the hopping roller 307, pinch rollers 308 and 309 and register rollers 310 and 311 are disposed for sandwiching the recording medium 305 to correct skew of the recording medium 305 and transporting the recording medium 305 to the process units 301 to 304. Note that the hopping roller 307 and the register rollers 310 and 311 are driven with a drive source and a gear (not shown).

In the process units 301 to 304, transfer rollers 312 formed of semi-conductive rubber and the likes are disposed at positions facing the photosensitive drums 301a to 304a. It is arranged such that a specific potential is generated between the surfaces of the photosensitive drums 301a to 304a and the transfer rollers 312, so that toner on the photosensitive drums 301a to 304a is attached to the recording medium 305.

In the embodiment, a fixing device 313 includes a heating roller and a back-up roller, so that toner transferred to the recording medium 305 is heated and pressed for fixing. Discharge roller 314 and 315 sandwich the recording medium 305 discharged from the fixing device 313 with pinch rollers 316 and 317, so that the recording medium 305 is transported to a recording medium stacker portion 318. Note that the discharge roller 314 and 315 are driven with a drive source and a gear (not shown). The LED unit is disposed in the exposure device 303c.

An operation of the image forming apparatus 300 will be explained next. First, the hopping roller 307 separates and transports the recording medium 305 stored in the sheet cassette 306 in a stacked state. Then, the photosensitive drum 301a and the transfer roller 312 sandwich the recording medium 305 to transfer a toner image to the recording medium 305, while the photosensitive drum 301a rotates to transport the recording medium 305.

Similar to the process described above, the recording medium 305 sequentially passes through the process units 301 to 304. Accordingly, the developing devices 301d to 304d develop the latent images formed with the exposure devices 301c to 304c to form the toner images in colors, and the toner images are sequentially transferred and overlapped on the recording medium 305.

After the toner images are overlapped on the recording medium 305, the fixing device 313 fixes the toner images. Afterward, the discharge rollers 314 and 315 and the pinch rollers 316 and 317 sandwich the recording medium 305 to discharge to the recording medium stacker portion 318 outside the image forming apparatus 300. Through the process described above, a color image is formed on the recording medium 305.

As described above, with the LED head using the semiconductor combined device in the first to eighth embodiments, it is possible to provide the image forming apparatus with improved quality and high reliability.

The disclosure of Japanese Patent Application No. 2006-202118, filed on Jul. 25, 2006, is incorporated in the application by reference.

While the invention has been explained with reference to the specific embodiments of the invention, the explanation is illustrative and the invention is limited only by the appended claims.

What is claimed is:

1. A semiconductor combined device, comprising:
a first substrate; and
a light emitting element disposed on the first substrate, said light emitting element including a mesa slope inclined relative to the substrate by a first angle; a light emitting portion extending in parallel to the first substrate; a first interlayer insulation layer covering the mesa slope and having a surface at the mesa slope inclined relative to the first substrate by a second angle smaller than the first angle; an electrode connected to the light emitting portion; and a protection layer covering the light emitting portion.

2. The semiconductor combined device according to claim 1, further comprising a second substrate and a drive circuit disposed on the second substrate.

3. The semiconductor combined device according to claim 1, wherein said first interlayer insulation layer is formed of an organic insulation material including at least one of a phenolic resin, a cresol resin, a quinone-azide derivative, an azide compound derivative, an indene-carboxylic acid.

4. The semiconductor combined device according to claim 1, wherein said protection layer is formed of an inorganic material including at least one of SiN, SiON, SiO₂, and Al₂O₃.

5. The semiconductor combined device according to claim 1, wherein said protection layer is arranged to cover at lease a side surface of the electrode so that the protection layer has a surface inclined relative to the substrate by a angle smaller than that of the side surface.

6. The semiconductor combined device according to claim 1, wherein said protection layer is formed of an organic insulation material including at least one of a phenolic resin, a cresol resin, a quinone-azide derivative, an azide compound derivative, an indene-carboxylic acid.

7. The semiconductor combined device according to claim 1, further comprising a second interlayer insulation layer disposed between the first interlayer insulation layer and the protection layer.

8. The semiconductor combined device according to claim 7, wherein said second interlayer insulation layer includes an opening portion at the light emitting element, said electrode covering the opening portion.

9. The semiconductor combined device according to claim 1, further comprising a light blocking layer for blocking light emitting from the light emitting element.

10. The semiconductor combined device according to claim 2, wherein said second substrate is formed of silicon.

11. The semiconductor combined device according to claim 1, wherein said light emitting element is formed of GaAs, InP, GaAsP, InGaAsP, AlGaAsP, AlGaInP, GaInP, ZnO, or a nitride compound type semiconductor such as GaN, AlGaN, and InGaN.

12. The semiconductor combined device according to claim 1, wherein said first interlayer insulation layer has a thickness larger than 5.0 μm.

13. A light emitting diode head comprising the semiconductor combined device according to claim 1; a holding member for holding the semiconductor combined device; and a lens array.

14. An image forming apparatus comprising a photosensitive member; a charging device for charging a surface of the photosensitive member; the light emitting diode head according to claim 13 for selectively exposing the surface of the photosensitive member to form a static latent image; and a developing device for developing the static latent image.

15. A semiconductor combined device, comprising:
a first substrate; and
a light emitting element disposed on the first substrate, said light emitting element including a mesa slope; a light emitting portion extending in parallel to the first substrate; and an interlayer insulation layer covering the mesa slope, said interlayer insulation layer being separated from an adjacent light emitting element.

16. The semiconductor combined device according to claim 15, wherein said light emitting element disposed away from the adjacent light emitting element with a separation area therebetween, said interlayer insulation layer being separated from the adjacent light emitting element at the separation area.
